(19) United States
(12) Patent Application Publication
(10) Pub. No.: US 2026/0155792 A1
(43) Pub. Date: Jun. 4, 2026

(54) HYBRID DIFFERENTIAL AMPLIFIER AND METHOD THEREOF

(71) Applicant: Richtek Technology Corporation, Hsinchu (TW)

(72) Inventors: Yi-Kuang CHEN, Hsinchu (TW); Shao-Ming SUN, Hsinchu (TW); Ming-Jun HSIAO, Hsinchu (TW)

(21) Appl. No.: 19/032,466

(22) Filed: Jan. 21, 2025

(30) Foreign Application Priority Data
Dec. 2, 2024 (TW) 113146650

(51) Int. Cl. H03F 1/32; H03F 1/26

(52) U.S. Cl. CPC H03F 1/3211; H03F 1/26; H03F 2200/165; H03F 2200/351

(57) ABSTRACT

A hybrid amplifier includes: a first to fourth PWM circuit, comparing triangular wave signals and filter signals to generate PWM signals; a first processing circuit, generating pulse-width processed signals based on the PWM signals and the polarity of input signals; a judgment circuit, generating a selection signal based on the level of a differential input signal; a selection circuit, generating switching control signals according to the selection signal and the pulse-width processed signals; and a first and second power stage generating switching voltages based on the switching control signals to switch an inductor to generate output signals. When outside the light-load range, the first switching signal controls the switching voltage to toggle between a higher voltage level and ground, while the second switching signal approximates the fundamental frequency. When within the light-load range, the switching control signals control the switching voltage to toggle between a lower voltage level and ground.

### CROSS REFERENCE

The present invention claims priority to TW 113146650 filed on Dec. 2, 2024.

### BACKGROUND OF THE INVENTION

### Field of Invention

The present invention relates to a hybrid differential amplifier and method thereof, and more particularly, to a hybrid differential amplifier and method capable of increasing pulse width and thereby reducing electromagnetic interference.

### Description of Related Art

Power factor correction (PFC) circuits and switching amplifiers using totem-pole modulation frequently encounter challenges related to distortion and electromagnetic interference (EMI) near the zero-voltage crossover point.

FIG. 1 illustrates a prior art hybrid differential amplifier. This prior art hybrid differential amplifier requires an additional low dropout regulator (LDO) under no-load conditions to mitigate electromagnetic interference (EMI). During light-load operation, the pulse width may approach 0% or 100%. If the pulses are not precisely generated, distortion may increase. To address this issue, ultra-fast rise and fall times are often needed during rapid driving processes.

To overcome the above issues, particularly the distortion and electromagnetic interference effects in the zero-voltage crossover region under light-load conditions, the present invention proposes a hybrid differential amplifier and method using multi-stage pulse modulation techniques. This approach effectively increases pulse width and reduces electromagnetic interference, addressing the shortcomings of prior art.

### SUMMARY OF THE INVENTION

From one perspective, the present invention provides a hybrid differential amplifier configured to generate a differential output signal based on a differential input signal to drive a load, wherein the differential input signal includes a first input signal and a second input signal, and the differential output signal includes a first output signal and a second output signal. The hybrid differential amplifier comprises a first pulse-width modulation (PWM) circuit configured to generate a first PWM signal by comparing a first triangular wave signal with a first filtered signal, wherein the first filtered signal is related to the first input signal; a second PWM circuit configured to generate a second PWM signal by comparing the first triangular wave signal with a second filtered signal, wherein the second filtered signal is related to the second input signal; a third PWM circuit configured to generate a third PWM signal by comparing a second triangular wave signal with the first filtered signal; a fourth PWM circuit configured to generate a fourth PWM signal by comparing the second triangular wave signal with the second filtered signal; a first masking frequency-doubler circuit configured to generate a first pulse-width masking frequency-doubled signal and a second pulse-width masking frequency-doubled signal based on the first PWM signal and the second PWM signal, wherein, when the first input signal is positive, the first pulse-width masking frequency-doubled signal corresponds to a frequency-doubled signal of the first PWM signal, and when the first input signal is negative, the first pulse-width masking frequency-doubled signal is 0; when the second input signal is positive, the second pulse-width masking frequency-doubled signal corresponds to a frequency-doubled signal of the second PWM signal, and when the second input signal is negative, the second pulse-width masking frequency-doubled signal is 0; a signal judgment circuit configured to generate a path selection signal based on the level range of the differential input signal; a signal selection circuit configured to generate a first switching control signal and a second switching control signal based on the first pulse-width masking frequency-doubled signal, the second pulse-width masking frequency-doubled signal, the third PWM signal, and the fourth PWM signal, in response to the path selection signal; a first power stage circuit including a first plurality of transistors coupled to a first switching node, configured to generate a first switching voltage at the first switching node based on the first switching control signal, thereby switching a first inductor coupled to the first switching node to generate the first output signal; a second power stage circuit including a second plurality of transistors, configured to generate a second switching voltage at a second switching node based on the second switching control signal, thereby generating the second output signal; wherein when the path selection signal indicates that the differential input signal is outside a light-load range, the first switching control signal is selected as being related to the first pulse-width masking frequency-doubled signal with a first PWM characteristic to control the first switching voltage at the first switching node to toggle between a first supply voltage and a ground potential, and the second switching control signal is selected as being approximating a fundamental frequency to control the second switching voltage at the second switching node to toggle between the first supply voltage and the ground potential, wherein the differential input signal has the fundamental frequency; wherein when the path selection signal indicates that the differential input signal is within the light-load range, the first switching control signal is selected as being related to the third PWM signal to control the first switching voltage to toggle between a second supply voltage and the ground potential, thereby switching the first inductor to generate the first output signal, and the second switching control signal is selected as being related to the fourth PWM signal to control the second switching voltage to toggle between the second supply voltage and the ground potential, wherein the second supply voltage is lower than the first supply voltage.

In one preferred embodiment, the first triangular wave signal and the second triangular wave signal have a common-mode offset and respective first and second amplitudes, wherein the first amplitude is either equal to the second amplitude with a nonzero common-mode offset or different from the second amplitude.

In one preferred embodiment, the second switching voltage either switches a second inductor with an inductance smaller than that of the first inductor to generate the second output signal or corresponds to the second output signal.

In one preferred embodiment, the differential input signal has an input common-mode level, and the path selection signal includes a light-load selection signal and a level selection signal. The signal judgment circuit generates the light-load selection signal based on whether the differential input signal is within a light-load range and generates the level selection signal based on the first pulse-width masking frequency-doubled signal and the second pulse-width masking frequency-doubled signal. The level selection signal represents a comparison between the differential input signal and the input common-mode level.

In one preferred embodiment, the signal judgment circuit includes a flip-flop configured to reset based on an inverted signal of the second pulse-width masking frequency-doubled signal and, in a non-reset state, to enable the level selection signal based on a trigger of the first pulse-width masking frequency-doubled signal.

In one preferred embodiment, the signal judgment circuit is further configured to compare an offset triangular wave with the differential input signal to generate a fifth PWM signal and a sixth PWM signal, wherein the offset triangular wave is obtained by superimposing the first triangular wave signal with a nonzero common-mode offset related to the light-load range; and to periodically determine, based on an operating cycle of the offset triangular wave, whether each of the fifth PWM signal and the sixth PWM signal includes a pulse within the previous operating cycle, thereby determining whether the level of the differential input signal is within the light-load range.

In one preferred embodiment, when the path selection signal indicates that the differential input signal is outside the light-load range and greater than the input common-mode level, the signal selection circuit controls the first switching control signal to toggle based on the first pulse-width masking frequency-doubled signal, and the second switching control signal to toggle based on the second pulse-width masking frequency-doubled signal; wherein when the path selection signal indicates that the differential input signal is outside the light-load range and less than the input common-mode level, the signal selection circuit controls the first switching control signal to toggle based on an inverted signal of the second pulse-width masking frequency-doubled signal, and the second switching control signal to toggle based on an inverted signal of the first pulse-width masking frequency-doubled signal.

In one preferred embodiment, when the path selection signal indicates that the differential input signal is within the light-load range, the signal selection circuit controls the first switching control signal to toggle based on the third PWM signal, and the second switching control signal to toggle based on the fourth PWM signal.

In one preferred embodiment, the hybrid differential amplifier further includes a second masking frequency-doubler circuit configured to generate a third pulse-width masking frequency-doubled signal and a fourth pulse-width masking frequency-doubled signal based on the third PWM signal and the fourth PWM signal, wherein, when the first input signal is positive, the third pulse-width masking frequency-doubled signal corresponds to a frequency-doubled signal of the third PWM signal, and when the first input signal is negative, the third pulse-width masking frequency-doubled signal is 0; when the second input signal is positive, the fourth pulse-width masking frequency-doubled signal corresponds to a frequency-doubled signal of the fourth PWM signal, and when the second input signal is negative, the fourth pulse-width masking frequency-doubled signal is 0; wherein when the path selection signal indicates that the differential input signal is within the light-load range and greater than the input common-mode level, the first switching control signal is controlled to toggle based on the third pulse-width masking frequency-doubled signal, and the second switching control signal is controlled to toggle based on the fourth pulse-width masking frequency-doubled signal; wherein when the path selection signal indicates that the differential input signal is within the light-load range and less than the input common-mode level, the first switching control signal is controlled to toggle based on an inverted signal of the fourth pulse-width masking frequency-doubled signal, and the second switching control signal is controlled to toggle based on an inverted signal of the third pulse-width masking frequency-doubled signal.

In one preferred embodiment, the first masking frequency-doubler circuit applies an AND logic operation to the first PWM signal and an inverted signal of the second PWM signal to generate the first pulse-width masking frequency-doubled signal, and applies an AND logic operation to an inverted signal of the first PWM signal and the second PWM signal to generate the second pulse-width masking frequency-doubled signal.

In one preferred embodiment, the first masking frequency-doubler circuit applies an AND logic operation to the first PWM signal and an inverted signal of the second PWM signal to generate the first pulse-width masking frequency-doubled signal, and applies an AND logic operation to an inverted signal of the first PWM signal and the second PWM signal to generate the second pulse-width masking frequency-doubled signal; the second masking frequency-doubler circuit applies an AND logic operation to the third PWM signal and an inverted signal of the fourth PWM signal to generate the third pulse-width masking frequency-doubled signal, and applies an AND logic operation to an inverted signal of the third PWM signal and the fourth PWM signal to generate the fourth pulse-width masking frequency-doubled signal.

In one preferred embodiment, the first power stage circuit includes a first primary high-side transistor, a first auxiliary high-side transistor, and a first low-side transistor, wherein the first primary high-side transistor is coupled between the first supply voltage and the first switching node; the first auxiliary high-side transistor is coupled between the second supply voltage and the first switching node; the first low-side transistor is coupled between the first switching node and the ground potential. The first power stage circuit is configured to generate the first switching voltage based on the first switching control signal to switch the first inductor, thereby converting the first supply voltage and the second supply voltage to generate the first output signal. The second power stage circuit includes a second primary high-side transistor, a second auxiliary high-side transistor, and a second low-side transistor, wherein the second primary high-side transistor is coupled between the first supply voltage and the second switching node; the second auxiliary high-side transistor is coupled between the second supply voltage and the second switching node; the second low-side transistor is coupled between the second switching node and the ground potential. The second power stage circuit is configured to switch based on the second switching control signal to convert the first supply voltage and the second supply voltage to generate the second output signal.

In one preferred embodiment, the hybrid differential amplifier further includes an error amplifier configured to generate an error amplified signal based on a difference between a feedback signal related to the second output signal and the second filtered signal, wherein in an ultra-light-load range, the signal selection circuit selects the error amplified signal to linearly control the second primary high-side transistor, adjusting the second output signal to be linearly related to the second filtered signal; wherein the ultra-light-load range is a subset of the light-load range and represents conditions with load levels smaller than those in the light-load range.

From another perspective, the present invention provides a hybrid differential amplification method for controlling a hybrid differential amplifier to generate a differential output signal based on a differential input signal to drive a load, wherein the differential input signal includes a first input signal and a second input signal, and the differential output signal includes a first output signal and a second output signal. The hybrid differential amplification method comprises: generating a first pulse-width modulation (PWM) signal by comparing a first triangular wave signal with a first filtered signal, wherein the first filtered signal is related to the first input signal; generating a second PWM signal by comparing the first triangular wave signal with a second filtered signal, wherein the second filtered signal is related to the second input signal; generating a third PWM signal by comparing a second triangular wave signal with the first filtered signal; generating a fourth PWM signal by comparing the second triangular wave signal with the second filtered signal; generating a first pulse-width masking frequency-doubled signal and a second pulse-width masking frequency-doubled signal based on the first PWM signal and the second PWM signal, wherein: when the first input signal is positive, the first pulse-width masking frequency-doubled signal corresponds to a frequency-doubled signal of the first PWM signal, and when the first input signal is negative, the first pulse-width masking frequency-doubled signal is 0; when the second input signal is positive, the second pulse-width masking frequency-doubled signal corresponds to a frequency-doubled signal of the second PWM signal, and when the second input signal is negative, the second pulse-width masking frequency-doubled signal is 0; generating a path selection signal based on the level range of the differential input signal; generating a first switching control signal and a second switching control signal based on the first pulse-width masking frequency-doubled signal, the second pulse-width masking frequency-doubled signal, the third PWM signal, and the fourth PWM signal, in response to the path selection signal; generating a first switching voltage at a first switching node based on the first switching control signal, thereby switching a first inductor coupled to the first switching node to generate the first output signal; generating a second switching voltage at a second switching node based on the second switching control signal, thereby generating the second output signal; wherein when the path selection signal indicates that the differential input signal is outside a light-load range, the first switching control signal is selected as being related to the first pulse-width masking frequency-doubled signal with a first PWM characteristic to control the first switching voltage at the first switching node to toggle between a first supply voltage and a ground potential, and the second switching control signal is selected as being related to a signal approximating a fundamental frequency to control the second switching voltage at the second switching node to toggle between the first supply voltage and the ground potential, wherein the differential input signal has the fundamental frequency; wherein when the path selection signal indicates that the differential input signal is within the light-load range, the first switching control signal is selected as being related to the third PWM signal to control the first switching voltage to toggle between a second supply voltage and a ground potential, thereby switching the first inductor to generate the first output signal, and the second switching control signal is selected as being related to the fourth PWM signal to control the second switching voltage to toggle between the second supply voltage and a ground potential; wherein the second supply voltage is lower than the first supply voltage.

In one preferred embodiment, the first triangular wave signal and the second triangular wave signal have a common-mode offset and respective first and second amplitudes, wherein the first amplitude is either equal to the second amplitude with a nonzero common-mode offset, or different from the second amplitude.

In one preferred embodiment, the second switching voltage either switches a second inductor with an inductance smaller than that of the first inductor to generate the second output signal, or corresponds to the second output signal.

In one preferred embodiment, the differential input signal has an input common-mode level, and the path selection signal includes a light-load selection signal and a level selection signal, wherein the step of generating the path selection signal includes generating the light-load selection signal based on whether the differential input signal is within a light-load range and generating the level selection signal based on the first pulse-width masking frequency-doubled signal and the second pulse-width masking frequency-doubled signal; the level selection signal represents a comparison between the differential input signal and the input common-mode level.

In one preferred embodiment, the step of generating the level selection signal includes: resetting the level selection signal based on an inverted signal of the second pulse-width masking frequency-doubled signal; and in a non-reset state, enabling the level selection signal based on a trigger of the first pulse-width masking frequency-doubled signal.

In one preferred embodiment, the step of generating the light-load selection signal includes: comparing an offset triangular wave with the differential input signal to generate a fifth PWM signal and a sixth PWM signal, wherein the offset triangular wave is obtained by superimposing the first triangular wave signal with a nonzero common-mode offset related to the light-load range; and periodically determining, based on an operating cycle of the offset triangular wave, whether each of the fifth PWM signal and the sixth PWM signal includes a pulse within the previous operating cycle, thereby determining whether the level of the differential input signal is within the light-load range.

In one preferred embodiment, the step of generating the level selection signal includes: when the path selection signal indicates that the differential input signal is outside the light-load range and greater than the input common-mode level, controlling the first switching control signal to toggle based on the first pulse-width masking frequency-doubled signal and controlling the second switching control signal to toggle based on the second pulse-width masking frequency-doubled signal; and when the path selection signal indicates that the differential input signal is outside the light-load range and less than the input common-mode level, controlling the first switching control signal to toggle based on an inverted signal of the second pulse-width masking frequency-doubled signal and controlling the second switching control signal to toggle based on an inverted signal of the first pulse-width masking frequency-doubled signal.

In one preferred embodiment, the step of generating the first switching control signal and the second switching control signal includes: when the path selection signal indicates that the differential input signal is within the light-load range, controlling the first switching control signal to toggle based on the third PWM signal and controlling the second switching control signal to toggle based on the fourth PWM signal.

In one preferred embodiment, the hybrid differential amplification method further includes generating a third pulse-width masking frequency-doubled signal and a fourth pulse-width masking frequency-doubled signal based on the third PWM signal and the fourth PWM signal, wherein: when the first input signal is positive, the third pulse-width masking frequency-doubled signal corresponds to a frequency-doubled signal of the third PWM signal, and when the first input signal is negative, the third pulse-width masking frequency-doubled signal is 0; when the second input signal is positive, the fourth pulse-width masking frequency-doubled signal corresponds to a frequency-doubled signal of the fourth PWM signal, and when the second input signal is negative, the fourth pulse-width masking frequency-doubled signal is 0; wherein when the path selection signal indicates that the differential input signal is within the light-load range and greater than the input common-mode level, the first switching control signal is controlled to toggle based on the third pulse-width masking frequency-doubled signal and the second switching control signal is controlled to toggle based on the fourth pulse-width masking frequency-doubled signal; wherein when the path selection signal indicates that the differential input signal is within the light-load range and less than the input common-mode level, the first switching control signal is controlled to toggle based on an inverted signal of the fourth pulse-width masking frequency-doubled signal and the second switching control signal is controlled to toggle based on an inverted signal of the third pulse-width masking frequency-doubled signal.

In one preferred embodiment, the step of generating the first pulse-width masking frequency-doubled signal and the second pulse-width masking frequency-doubled signal includes: applying an AND logic operation to the first PWM signal and an inverted signal of the second PWM signal to generate the first pulse-width masking frequency-doubled signal; and applying an AND logic operation to an inverted signal of the first PWM signal and the second PWM signal to generate the second pulse-width masking frequency-doubled signal.

In one preferred embodiment, the step of generating the first pulse-width masking frequency-doubled signal and the second pulse-width masking frequency-doubled signal includes: applying an AND logic operation to the first PWM signal and an inverted signal of the second PWM signal to generate the first pulse-width masking frequency-doubled signal; and applying an AND logic operation to an inverted signal of the first PWM signal and the second PWM signal to generate the second pulse-width masking frequency-doubled signal;
wherein the step of generating the third pulse-width masking frequency-doubled signal and the fourth pulse-width masking frequency-doubled signal includes: applying an AND logic operation to the third PWM signal and an inverted signal of the fourth PWM signal to generate the third pulse-width masking frequency-doubled signal; and applying an AND logic operation to an inverted signal of the third PWM signal and the fourth PWM signal to generate the fourth pulse-width masking frequency-doubled signal.

In one preferred embodiment, the hybrid differential amplification method further includes generating an error amplified signal based on a difference between a feedback signal related to the second output signal and the second filtered signal, wherein in an ultra-light-load range, the error amplified signal is selected to linearly control the second primary high-side transistor, adjusting the second output signal to be linearly related to the second filtered signal; wherein the ultra-light-load range is a subset of the light-load range and represents conditions with load levels smaller than those in the light-load range.

The objectives, technical details, features, and effects of the present invention will be better understood with regard to the detailed description of the embodiments below, with reference to the attached drawings.

### BRIEF DESCRIPTION OF THE DRAWINGS

FIG. 1 illustrates a prior art hybrid differential amplifier.

FIG. 2A illustrates a block diagram of a hybrid differential amplifier according to an embodiment of the present invention.

FIG. 2B illustrates a specific embodiment of the power stage circuits and the signal selection circuit (201) in the hybrid differential amplifier according to one embodiment of the invention.

FIG. 3 illustrates signal waveforms related to the hybrid differential amplifier according to one embodiment of the present invention.

FIG. 4 illustrates another embodiment of the hybrid differential amplifier, showing a specific embodiment of the masking frequency-doubler circuit and the signal selection circuit.

FIG. 5 illustrates the waveform diagram of signals corresponding to the embodiment of the hybrid differential amplifier shown in FIG. 4.

FIG. 6 illustrates a schematic diagram of the signal judgment circuit in the hybrid differential amplifier according to an embodiment of the present invention.

FIG. 7A illustrates the waveform diagram of signals in prior art hybrid differential amplifiers.

FIG. 7B illustrates the waveform diagram of signals in the hybrid differential amplifier according to one embodiment of the present invention.

FIG. 7C illustrates the waveform diagram of signals in the hybrid differential amplifier according to another embodiment of the present invention.

FIG. 8A shows an enlarged view of a portion of FIG. 7A.

FIG. 8B shows an enlarged view of a portion of FIG. 7B.

FIG. 8C shows an enlarged view of a portion of FIG. 7C.

FIG. 9 illustrates the schematic diagram of a specific embodiment of a portion of the signal selection circuit and power stage circuit in the hybrid differential amplifier according to the present invention.

FIG. 10 illustrates a waveform diagram for generating the light-load selection signal SEL_LL in one embodiment of the present invention.

FIGS. 11a to 11d illustrate signal waveforms associated with the hybrid differential amplifier according to an embodiment of the present invention.

FIG. 12 illustrates a schematic diagram of an alternative embodiment of power stage circuits of the hybrid differential amplifier according to the present invention.

FIG. 13A illustrates a specific embodiment of the pulse-width modulation circuits and masking frequency-doubler circuits in the hybrid differential amplifier according to one embodiment of the present invention.

FIG. 13B illustrates another specific embodiment of the pulse-width modulation circuits and masking frequency-doubler circuits in the hybrid differential amplifier according to an alternative embodiment of the present invention.

FIG. 14 illustrates the waveform diagram of signals corresponding to the embodiments shown in FIG. 13A and FIG. 13B.

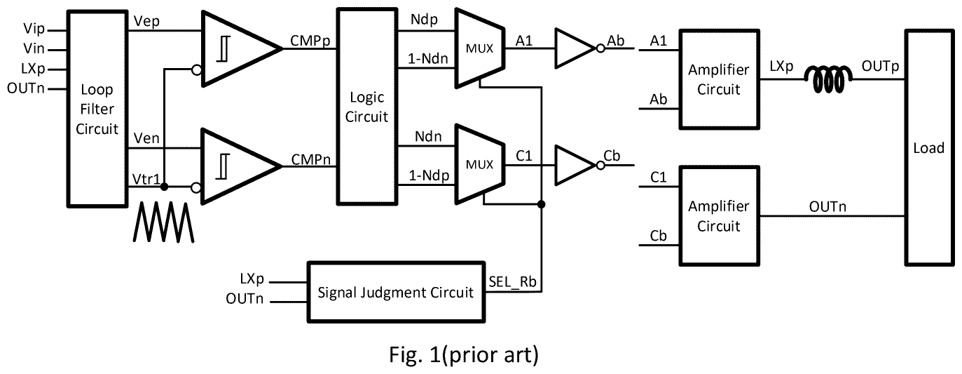

### DESCRIPTION OF THE PREFERRED EMBODIMENTS

The drawings as referred to throughout the description of the present invention are for illustration only, to show the interrelations between the circuits and the signal waveforms, but not drawn according to actual scale of circuit sizes and signal amplitudes and frequencies.

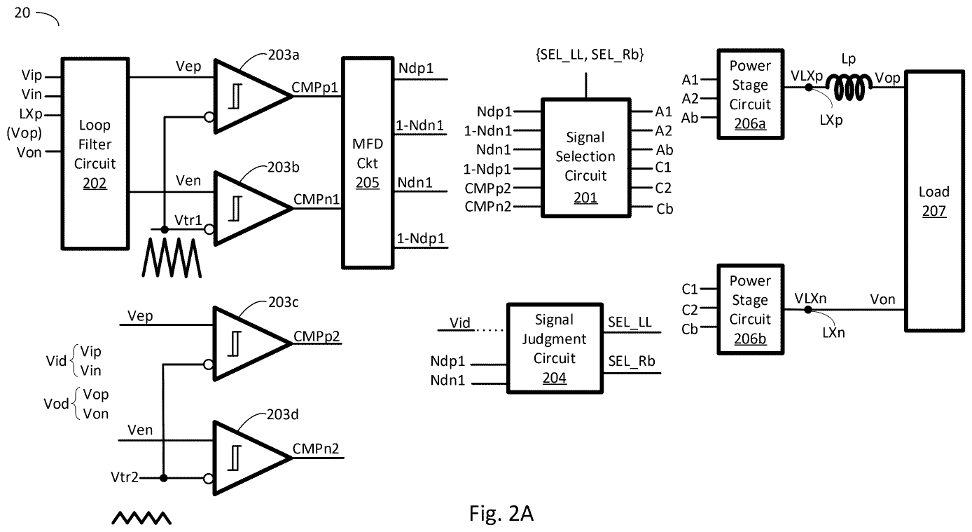

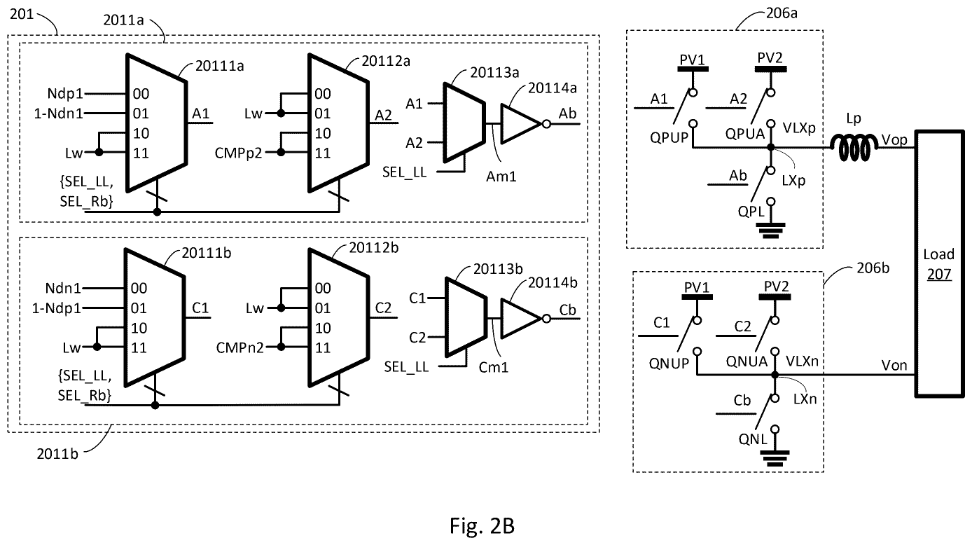

FIG. 2A illustrates a block diagram of a hybrid differential amplifier according to an embodiment of the present invention. As shown in FIG. 2A, the hybrid differential amplifier 20 generates a differential output signal Vod, which is the difference between output signals Vop and Von, based on a differential input signal Vid, which is the difference between input signals Vip and Vin, to drive a load 207. The differential input signal Vid includes input signals Vip and Vin, while the differential output signal Vod includes output signals Vop and Von. The hybrid differential amplifier 20 comprises a signal selection circuit 201, a loop filter circuit 202, pulse-width modulation circuits 203a to 203d, a signal judgment circuit 204, a masking frequency-doubler circuit (MFD Ckt 205), and power stage circuits 206a and 206b.

The input signals Vip and Vin, as well as the output signals Vop and Von, correspond to the positive and negative input signals and the positive and negative output signals, respectively, where “positive” and “negative” are defined relative to their respective common-mode levels and phases, not in absolute terms. Furthermore, the concept of the present invention can also be applied when “positive” and “negative” are swapped.

The loop filter circuit 202 amplifies and filters the difference between the differential output signal Vod and the differential input signal Vid to generate filtered signals Vep and Ven. The pulse-width modulation circuit 203a generates a pulse-width modulation signal CMPp1 by comparing a triangular wave signal Vtr1 with the filtered signal Vep, where the filtered signal Vep is related to the input signal Vip. Similarly, the pulse-width modulation circuit 203b generates a pulse-width modulation signal CMPn1 by comparing the triangular wave signal Vtr1 with the filtered signal Ven, where the filtered signal Ven is related to the input signal Vin.

The pulse-width modulation circuit 203c generates a pulse-width modulation signal CMPp2 by comparing a second triangular wave signal Vtr2 with the filtered signal Vep, while the pulse-width modulation circuit 203d generates a pulse-width modulation signal CMPn2 by comparing the triangular wave signal Vtr2 with the filtered signal Ven.

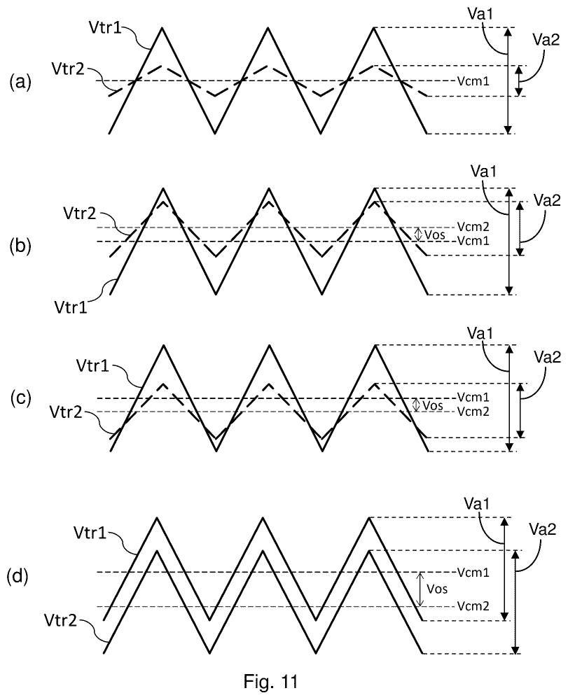

Referring to FIGS. 11a to 11d, which illustrate signal waveforms associated with the hybrid differential amplifier according to an embodiment of the present invention, the triangular wave signals Vtr1 and Vtr2 are shown. As illustrated in FIGS. 11a to 11d, there is a common-mode offset Vos between the triangular wave signals Vtr1 and Vtr2, and each has respective amplitudes Va1 and Va2. In one embodiment, as shown in FIGS. 11a to 11c, the amplitude Va1 differs from the amplitude Va2. In one embodiment, Va1 is greater than Va2, and the common-mode offset Vos can be zero as in FIG. 11a, or non-zero as in FIGS. 11b and 11c. In another embodiment, as shown in FIG. 11d, the amplitudes Va1 and Va2 are equal, and the common-mode offset Vos is non-zero.

The pulse-width modulation signals CMPp1, CMPn1, CMPp2, and CMPn2 correspond to pulse-width modulation signals after a basic Class-D pulse-width modulation process. In the present invention, these pulse-width modulation signals are further processed to achieve the aforementioned functionality and objectives, as detailed later.

Referring again to FIG. 2A, the masking frequency-doubler circuit 205 generates pulse-width masking frequency-doubled signals Ndp1, 1-Ndp1, Ndn1, and 1-Ndn1 based on the pulse-width modulation signals CMPp1 and CMPn1. The masking frequency-doubler circuit 205 performs logical operations on the pulse-width modulation signals CMPp1 and CMPn1, such that when the input signal Vip is positive, the pulse-width masking frequency-doubled signal Ndp1 corresponds to a frequency-doubled pulse-width modulation signal derived from pulse-width modulation signal CMPp1, and when the input signal Vip is negative, Ndp1 is zero. Similarly, when the input signal Vin is positive, the pulse-width masking frequency-doubled signal Ndn1 corresponds to a frequency-doubled pulse-width modulation signal derived from pulse-width modulation signal CMPn1, and when the input signal Vin is negative, Ndn1 is zero.

The signal judgment circuit 204 is configured to generate a level selection signal SEL_Rb and a light-load selection signal SEL_LL based on the level range of the differential input signal Vid, the pulse-width masking frequency-doubled signal Ndp1, and the pulse-width masking frequency-doubled signal Ndn1. Specifically, the signal judgment circuit 204 generates the light-load selection signal SEL_LL based on the differential input signal Vid. In this embodiment, the enable level of the light-load selection signal SEL_LL (e.g., 1) indicates that the differential input signal Vid is within the light-load range. Additionally, the signal judgment circuit 204 generates the level selection signal SEL_Rb based on the pulse-width masking frequency-doubled signals Ndp1 and Ndn1. The level selection signal SEL_Rb indicates the comparison between the differential input signal Vid and the input common-mode level Vicm. Specifically, in this embodiment, the enable level of SEL_Rb (e.g., 1) indicates that the differential input signal Vid is greater than the input common-mode level Vicm.

The signal selection circuit 201 is configured to generate the switching control signals A1, A2, Ab, C1, C2, and Cb to control the power stage circuits 206a and 206b based on the path selection signals SEL (including the level selection signal SEL_Rb and the light-load selection signal SEL_LL). The signal selection circuit 201 selects among the pulse-width masking frequency-doubled signals Ndp1, 1-Ndp1, Ndn1, 1-Ndn1, and the pulse-width modulation signals CMPp2 and CMPn2 to generate the aforementioned switching control signals.

The power stage circuit 206a generates a switching voltage VLXp at the switching node LXp based on the switching control signals A1, A2, and Ab. This switching voltage VLXp drives the inductor Lp coupled to the switching node LXp to generate the output signal Vop. Similarly, the power stage circuit 206b generates a switching voltage VLXn at the switching node LXn based on the switching control signals C1, C2, and Cb, thereby generating the output signal Von. In this embodiment, the switching voltage VLXn corresponds to the output signal Von.

FIG. 2B illustrates a specific embodiment of the power stage circuits (206a and 206b) and the signal selection circuit (201) in the hybrid differential amplifier according to one embodiment of the invention. As shown in FIG. 2B, the power stage circuit 206a includes a primary high-side transistor QPUP, an auxiliary high-side transistor QPUA, and a low-side transistor QPL. The primary high-side transistor QPUP is coupled between the supply voltage PV1 and the switching node LXp. The auxiliary high-side transistor QPUA is coupled between the supply voltage PV2 and the switching node LXp. The low-side transistor QPL is coupled between the switching node LXp and the ground potential. The power stage circuit 206a generates the switching voltage VLXp based on the switching control signals A1, A2, and Ab to toggle the inductor Lp, converting the supply voltages PV1 and PV2 to generate the output signal Vop. The power stage circuit 206b includes a primary high-side transistor QNUP, an auxiliary high-side transistor QNUA, and a low-side transistor QNL. The primary high-side transistor QNUP is coupled between the supply voltage PV1 and the switching node LXn. The auxiliary high-side transistor QNUA is coupled between the supply voltage PV2 and the switching node LXn. The low-side transistor QNL is coupled between the switching node LXn and the ground potential. The circuit toggles based on the switching control signals C1, C2, and Cb, converting the supply voltages PV1 and PV2 to generate the output signal Von.

When the path selection signal SEL indicates that the differential input signal Vid is outside the light-load range, the switching control signals A1, A2, and Ab are selected as signals related to the pulse-width masking frequency-doubled signals Ndp1 and Ndn1 with a first pulse-width modulation characteristic. These signals control the switching voltage VLXp at the switching node LXp to toggle between the supply voltage PV1 and the ground potential. The switching control signals C1, C2, and Cb are selected as signals approximating the fundamental frequency, controlling the switching voltage VLXn at the switching node LXn to toggle between the supply voltage PV1 and the ground potential.

It should be noted that the fundamental frequency mentioned above refers to the frequency of variation of the differential input signal Vid. The “first pulse-width modulation characteristic” refers to the modulation characteristic of the pulse-width masking frequency-doubled signals Ndp1 and Ndn1 after the frequency-doubling and masking process.

More specifically, when the path selection signal SEL indicates that the differential input signal Vid is outside the light-load range and greater than the input common-mode level Vicm, the signal selection circuit 201 controls the switching control signals A1, A2, and Ab to toggle based on the pulse-width masking frequency-doubled signal Ndp1 and controls the switching control signals C1, C2, and Cb to toggle based on the pulse-width masking frequency-doubled signal Ndn1. When the path selection signal SEL indicates that the differential input signal Vid is outside the light-load range and less than the input common-mode level Vicm, the signal selection circuit 201 controls the switching control signals A1, A2, and Ab to toggle based on an inverted signal of the pulse-width masking frequency-doubled signal Ndn1 and controls the switching control signals C1, C2, and Cb to toggle based an inverted signal of the pulse-width masking frequency-doubled signal Ndp1.

On the other hand, when the path selection signal SEL indicates that the differential input signal Vid is within the light-load range, the switching control signals A1, A2, and Ab are selected as signals related to the pulse-width modulation signal CMPp2 to control the switching voltage VLXp to toggle between the supply voltage PV2 and the ground potential, thereby switching the inductor Lp to generate the output signal Vop. Similarly, the switching control signals C1, C2, and Cb are selected as signals related to the pulse-width modulation signal CMPn2 to control the switching voltage VLXn to toggle between the supply voltage PV2 and the ground potential. In one embodiment, the supply voltage PV2 is lower than the supply voltage PV1.

It is worth mentioning that the path selection signal SEL controls the signal selection circuit 201 to differentiate the operating modes of the hybrid differential amplifier based on the range of the differential input signal Vid. Specifically, it distinguishes between conditions inside and outside the light-load range. When outside the light-load range, the path selection signal further determines whether the differential input signal Vid is greater or less than the input common-mode level to enable corresponding control for totem-pole pulse-width modulation. Outside the light-load range, the signal selection circuit 201 controls the power stage circuits 206a and 206b to operate using the higher supply voltage PV1, performing totem-pole Class-D PWM operation. In this mode, the power stage circuit 206a drives the inductor Lp to generate the output signal Vop, while the power stage circuit 206b can directly output the signal Von with the fundamental frequency or output Von by switching a smaller inductor. This design reduces the overall circuit size and cost. (It should be noted that the totem-pole Class-D PWM operation refers to toggling the switching voltage VLXp at the pulse-width modulation frequency while toggling VLXn at the fundamental frequency.)

On the other hand, when the differential input signal Vid is within the light-load range, the power stage circuits 206a and 206b perform Class-D PWM operation using the lower supply voltage PV2. In this mode, the voltage amplitude of the switching voltages VLXp and VLXn is reduced, and the required duty cycle is increased. Such design effectively reduces distortion and electromagnetic interference near the zero-voltage crossover point.

As shown in FIG. 2B, in one specific embodiment, the signal selection circuit 201 comprises sub-circuits 2011a and 2011b. Sub-circuit 2011a includes multiplexers 20111a, 20112a, and 20113a, as well as an inverter 20114a. Multiplexer 20111a is configured to generate the switching control signal A1 based on the pulse-width masking frequency-doubled signals Ndp1, 1-Ndn1, and a low-level signal Lw (e.g., 0) in response to the level selection signal SEL_Rb and the light-load selection signal SEL_LL. Multiplexer 20112a generates the switching control signal A2 based on the pulse-width modulation signal CMPp2 and the low-level signal Lw in response to the level selection signal SEL_Rb and the light-load selection signal SEL_LL. Multiplexer 20113a generates an intermediate signal Am1 based on the switching control signals A1 and A2 in response to the light-load selection signal SEL_LL, and the inverter 20114a subsequently inverts Am1 to generate the switching control signal Ab.

Continuing with FIG. 2b, sub-circuit 2011b functions similarly. Multiplexer 20111b is configured to generate the switching control signal C1 based on the pulse-width masking frequency-doubled signals 1-Ndp1, Ndn1, and the low-level signal Lw in response to the level selection signal SEL_Rb and the light-load selection signal SEL_LL. Multiplexer 20112b generates the switching control signal C2 based on the pulse-width modulation signal CMPn2 and the low-level signal Lw in response to the level selection signal SEL_Rb and the light-load selection signal SEL_LL. Multiplexer 20113b generates an intermediate signal Cm1 based on the switching control signals C1 and C2 in response to the light-load selection signal SEL_LL, and the inverter 20114b inverts Cm1 to generate the switching control signal Cb.

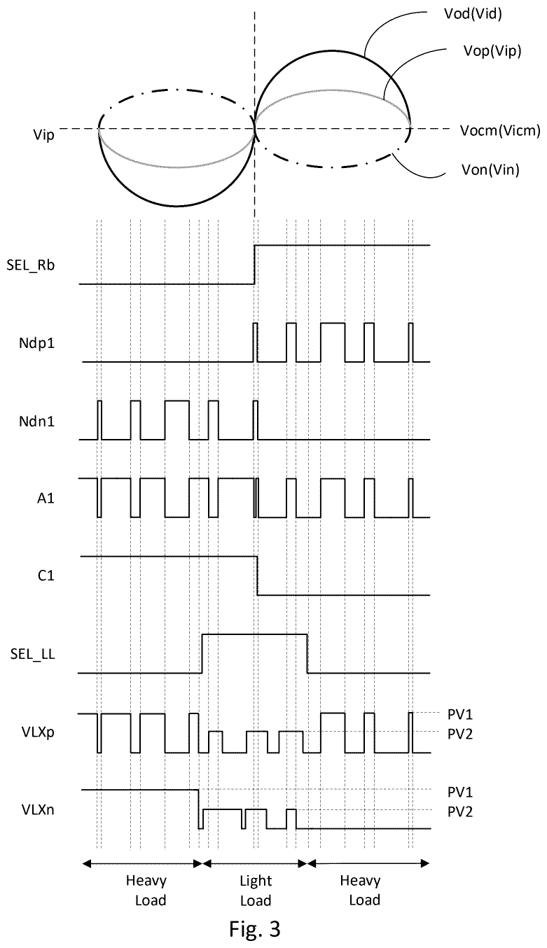

FIG. 3 illustrates signal waveforms related to the hybrid differential amplifier according to one embodiment of the present invention. The input signals Vip and Vin, output signals Vop and Von, differential output signal Vod, differential input signal Vid, input common-mode level Vicm, output common-mode level Vocm, level selection signal SEL_Rb, pulse-width masking frequency-doubled signals Ndp1 and Ndn1, switching control signals A1 and C1, light-load selection signal SEL_LL, and switching voltages VLXp and VLXn are all shown in FIG. 3. As depicted in FIG. 3, the differential input signal Vid has an input common-mode level Vicm. As shown in FIG. 3, when the light-load selection signal SEL_LL indicates that the differential input signal Vid is outside the light-load range and greater than the input common-mode level Vicm (as marked on the right side as the “heavy load” range), the switching control signal A1 toggles based on the pulse-width masking frequency-doubled signal Ndp1, and the switching control signal C1 toggles based on the pulse-width masking frequency-doubled signal Ndn1. When the light-load selection signal SEL_LL indicates that the differential input signal Vid is outside the light-load range and less than the input common-mode level Vicm (as marked on the left side as the “heavy load” range), the switching control signal A1 toggles based on the inverted signal of the pulse-width masking frequency-doubled signal Ndn1, and the switching control signal C1 toggles based on the inverted signal of the pulse-width masking frequency-doubled signal Ndp1.

As seen in FIG. 3, outside the light-load range, the switching voltages VLXp and VLXn toggle between the supply voltage PV1 and the ground potential using the aforementioned totem-pole Class-D pulse-width modulation (PWM). Within the light-load range, the switching voltages VLXp and VLXn toggle between the supply voltage PV2 and the ground potential using Class-D PWM.

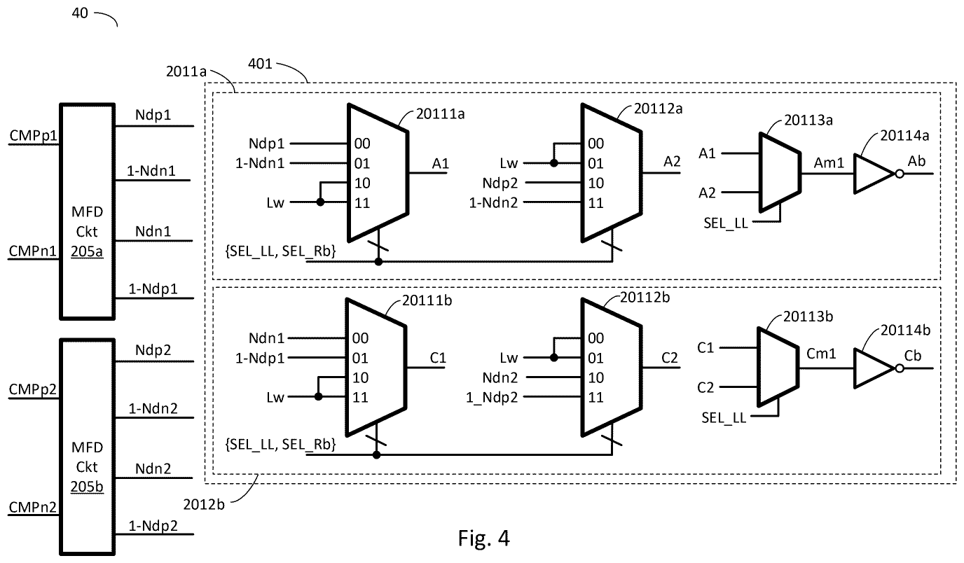

FIG. 4 illustrates another embodiment of the hybrid differential amplifier, showing a specific embodiment of the masking frequency-doubler circuit and the signal selection circuit. As shown in FIG. 4, this embodiment includes masking frequency-doubler circuits (MFD Ckt 205a and 205b). Masking frequency-doubler circuit 205a is similar to masking frequency-doubler circuit 205 in FIG. 2A and will not be described in detail. Masking frequency-doubler circuit 205b generates pulse-width masking frequency-doubled signals Ndp2, 1-Ndp2, Ndn2, and 1-Ndn2 based on pulse-width modulation signals CMPp2 and CMPn2. When the input signal Vip is positive, the pulse-width masking frequency-doubled signal Ndp2 corresponds to a frequency-doubled signal of the pulse-width modulation signal CMPp2, and when the input signal Vip is negative, the pulse-width masking frequency-doubled signal Ndp2 is 0. Similarly, when the input signal Vin is positive, the pulse-width masking frequency-doubled signal Ndn2 corresponds to a frequency-doubled signal of the pulse-width modulation signal CMPn2, and when the input signal Vin is negative, the pulse-width masking frequency-doubled signal Ndn2 is 0.

In this embodiment, when the path selection signal SEL indicates that the differential input signal Vid is outside the light-load range, its operation is identical to the embodiment shown in FIG. 2B. The difference in this embodiment lies in its operation when the path selection signal SEL indicates that the differential input signal Vid is within the light-load range. In such cases, the hybrid differential amplifier also adopts a totem-pole Class-D pulse-width modulation approach, with the switching voltages VLXp and VLXn toggling between the supply voltage PV2, which is lower than the supply voltage PV1, and the ground potential.

Specifically, when the path selection signal SEL indicates that the differential input signal Vid is within the light-load range and greater than the input common-mode level Vicm, the signal selection circuit 201 controls the switching control signals A1, A2, and Ab to toggle based on the pulse-width masking frequency-doubled signal Ndp2, and controls the switching control signals C1, C2, and Cb to toggle based on the pulse-width masking frequency-doubled signal Ndn2. When the path selection signal SEL indicates that the differential input signal Vid is within the light-load range and less than the input common-mode level Vicm, the signal selection circuit 201 controls the switching control signals A1, A2, and Ab to toggle based on the inverted signal of the pulse-width masking frequency-doubled signal Ndn2, and controls the switching control signals C1, C2, and Cb to toggle based on the inverted signal of the pulse-width masking frequency-doubled signal Ndp2.

As shown in FIG. 4, the signal selection circuit 401 in this embodiment is similar to the signal selection circuit 201 in FIG. 2B, with a few differences. Multiplexer 20112a is configured to generate the switching control signal A2 based on the pulse-width masking frequency-doubled signals Ndp2 and 1-Ndn2 and the low-level signal Lw in response to the level selection signal SEL_Rb and the light-load selection signal SEL_LL. Multiplexer 20112b is configured to generate the switching control signal C2 based on the pulse-width masking frequency-doubled signals Ndn2 and 1-Ndp2 and the low-level signal Lw in response to the level selection signal SEL_Rb and the light-load selection signal SEL_LL.

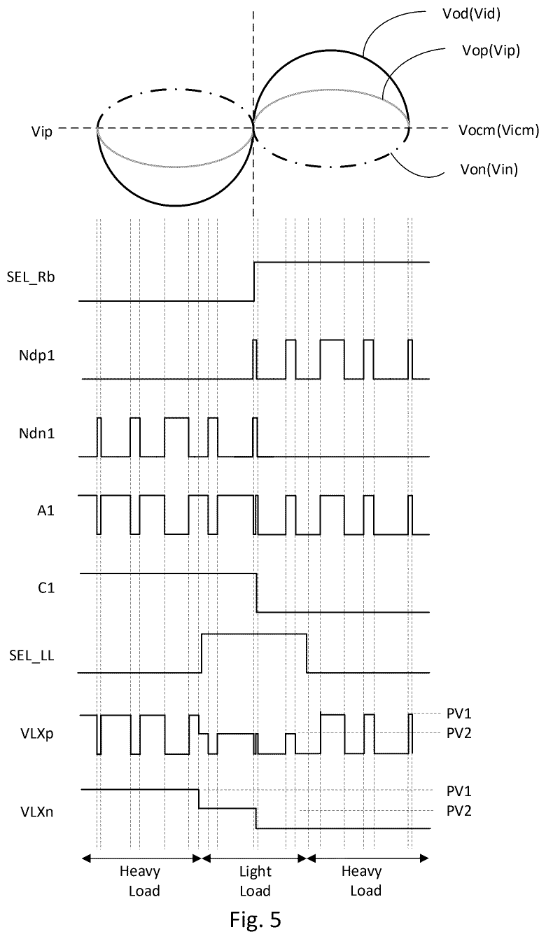

FIG. 5 illustrates the waveform diagram of signals corresponding to the embodiment of the hybrid differential amplifier shown in FIG. 4. Signals such as input signals Vip and Vin, output signals Vop and Von, differential output signal Vod, differential input signal Vid, input common-mode level Vicm, output common-mode level Vocm, level selection signal SEL_Rb, pulse-width masking frequency-doubled signals Ndp1 and Ndn1, switching control signals A1 and C1, light-load selection signal SEL_LL, and switching voltages VLXp and VLXn are shown in FIG. 5. As depicted, when the light-load selection signal SEL_LL indicates that the differential input signal Vid is outside the light-load range, the operation waveforms are identical to those shown in FIG. 3. On the other hand, when the light-load selection signal SEL_LL indicates that the differential input signal Vid is within the light-load range, the switching voltages VLXp and VLXn toggle using totem-pole Class-D pulse-width modulation between the supply voltage PV2 and the ground potential. The embodiment in FIG. 4 and FIG. 5 demonstrates that by lowering the voltage amplitude of switching voltages VLXp and VLXn near zero-voltage crossing points, the duty cycle is increased, effectively reducing distortion and electromagnetic interference.

FIG. 6 illustrates a schematic diagram of the signal judgment circuit in the hybrid differential amplifier according to an embodiment of the present invention. This embodiment shows a specific embodiment of the signal judgment circuit 204. The signal judgment circuit 204 includes a flip-flop 2041 configured to reset based on the inverted signal of the pulse-width masking frequency-doubled signal Ndn1 and, in a non-reset state, to enable the level selection signal SEL_Rb based on the trigger, for example the rising edge, of the pulse-width masking frequency-doubled signal Ndp1.

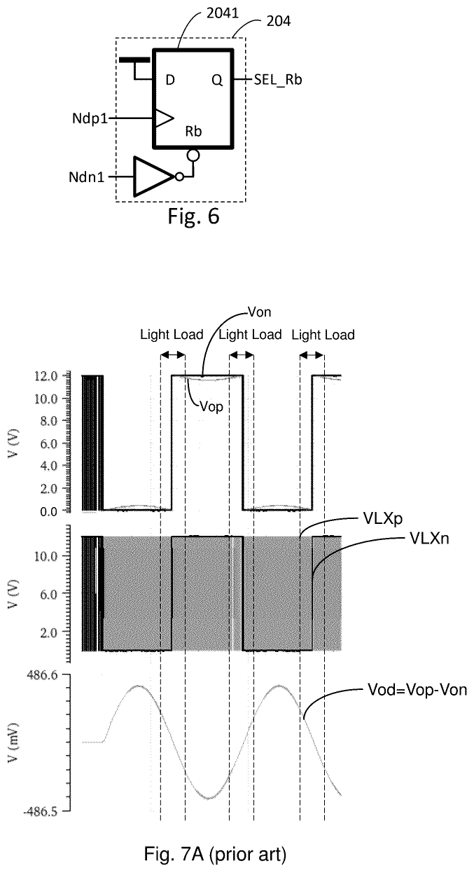

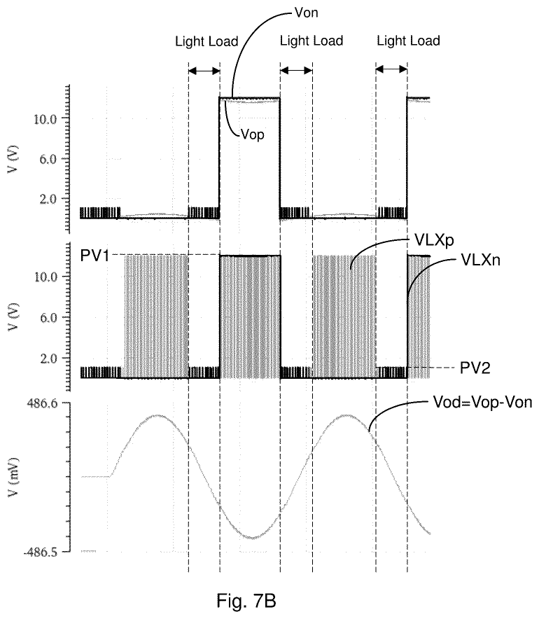

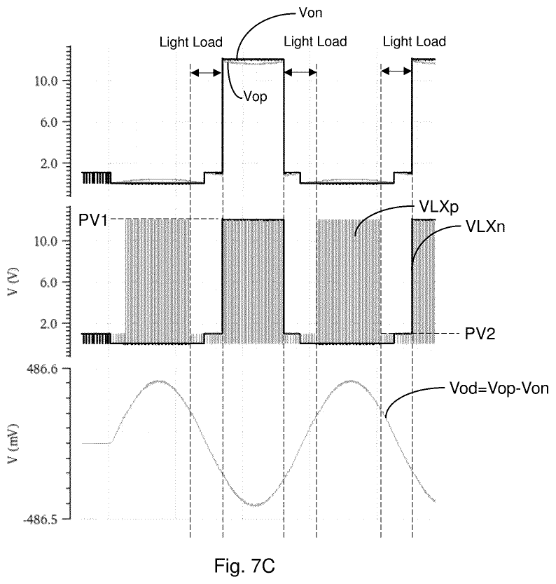

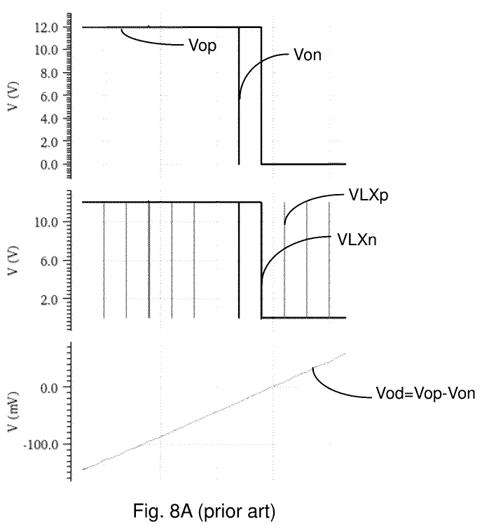

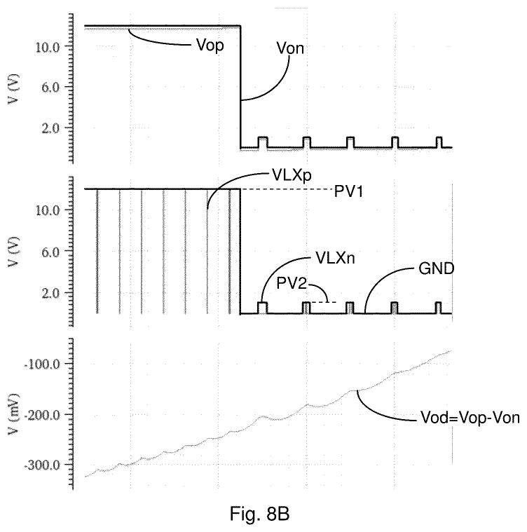

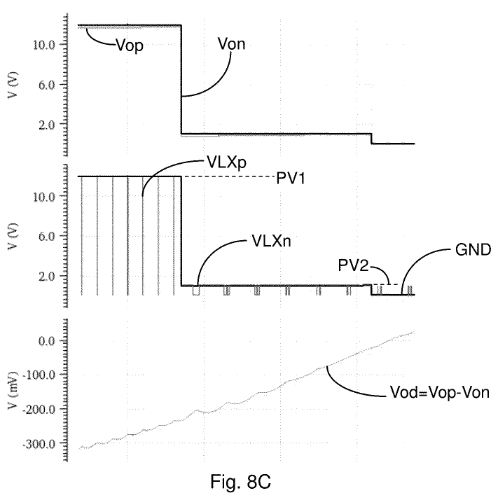

FIG. 7A illustrates the waveform diagram of signals in conventional hybrid differential amplifiers, and FIG. 8A shows an enlarged view of a portion of FIG. 7A. Signals such as output signals Vop and Von, switching voltages VLXp and VLXn, and differential output signal (i.e., Vop, Von) are shown in FIG. 7A and FIG. 8A. In prior art, regardless of whether the operation is inside or outside the light-load range, the switching voltages VLXp and VLXn toggle at higher levels between the supply voltage PV1 and the ground potential. As seen in FIG. 8A, under light-load conditions, the zero-voltage crossing region exhibits extremely narrow pulse widths, meaning very low duty cycles which, additionally due to the high switching voltage, causes higher electromagnetic interference.

FIG. 7B illustrates the waveform diagram of signals in the hybrid differential amplifier according to one embodiment of the present invention, while FIG. 8B shows an enlarged view of a portion of FIG. 7B. FIG. 7C illustrates another embodiment, and FIG. 8C shows an enlarged view of a portion of FIG. 7C. Signals such as output signals Vop and Von, switching voltages VLXp and VLXn, and differential output signal Vod are shown in FIG. 7B, FIG. 8B, FIG. 7C, and FIG. 8C. FIG. 7B and FIG. 8B correspond to the embodiment in FIG. 2B and FIG. 3, while FIG. 7C and FIG. 8C correspond to the embodiment in FIG. 4 and FIG. 5. As shown in FIG. 8B, in this embodiment, within the light-load range, the switching voltages VLXp and VLXn toggle using pulse-width modulation between the lower supply voltage PV2 and the ground potential. As shown in FIG. 8C, within the light-load range, the switching voltages VLXp and VLXn toggle using the totem-pole Class-D pulse-width modulation between the lower supply voltage PV2 and the ground potential. The reduction in electromagnetic interference is attributed to both the increased duty cycle and the lower supply voltage PV2.

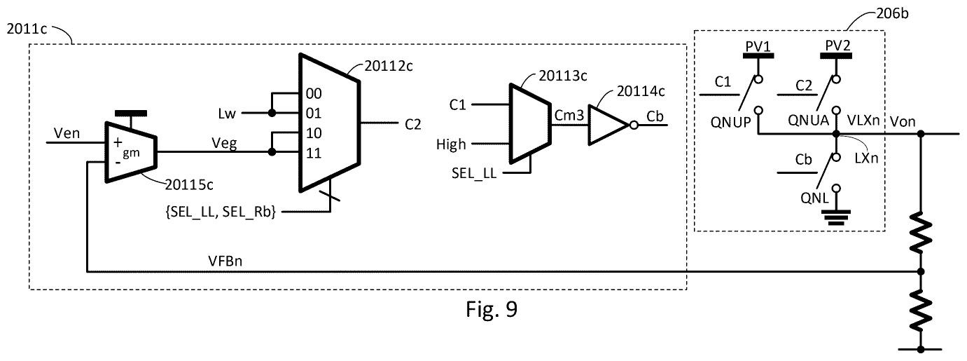

FIG. 9 illustrates the schematic diagram of a specific embodiment of a portion of the signal selection circuit and power stage circuit in the hybrid differential amplifier according to the present invention. The signal selection circuit 201 in this embodiment includes a signal selection sub-circuit 2011c, which includes multiplexers 20112c and 20113c, an inverter 20114c, and an error amplifier 20115c. The error amplifier 20115c generates an error amplified signal Veg based on the difference between the feedback signal VFBn related to the output signal Von and the filtered signal Ven. In the ultra-light-load range, the signal selection circuit 201 selects the error amplified signal Veg to linearly control the primary high-side transistor QNUP, adjusting the output signal Von to be linearly related to the filtered signal Ven. In one embodiment, the ultra-light-load range is a subset of the light-load range and represents smaller loads than those in the light-load range. In one example, the ultra-light-load range may include a no-load condition. In this embodiment, the ultra-light-load ranges shares at least one transistor with the light-load or heavy-load ranges. Specifically, in heavy-load the or light-load ranges, the primary high-side transistor QNUP, auxiliary high-side transistor QNUA, and low-side transistor QNL are controlled by switching control signals C1, C2, and Cb to toggle, causing the output signal Von to switch between supply voltages PV1, PV2, and the ground potential. In the ultra-light-load range, at least one of QNUP, QNUA, and QNL is linearly controlled based on the error amplified signal Veg, adjusting the output signal Von to a linear voltage output that is linearly related to the input signal Vin. This linear output voltage is between the supply voltage PV1 (or PV2) and the ground potential.

Continuing with FIG. 9, in this embodiment, the multiplexer 20112c selects between the error amplified signal Veg and a low-level signal Lw based on the level selection signal SEL_Rb and the light-load selection signal SEL_LL to generate the switching control signals C2, C1, and/or Cb. The multiplexer 20113c selects between switching control signal C1 and a high-level signal Hgh based on the light-load selection signal SEL_LL to generate an intermediate signal Cm3, which is then inverted by the inverter 20114c to generate switching control signal Cb. In this specific embodiment shown in FIG. 9, during the ultra-light-load range, the primary high-side transistor QNUP and the low-side transistor QNL are turned off, while the auxiliary high-side transistor QNUA is linearly controlled based on the error amplified signal Veg to adjust the output signal Von to a linear output voltage linearly related to the input signal Vin.

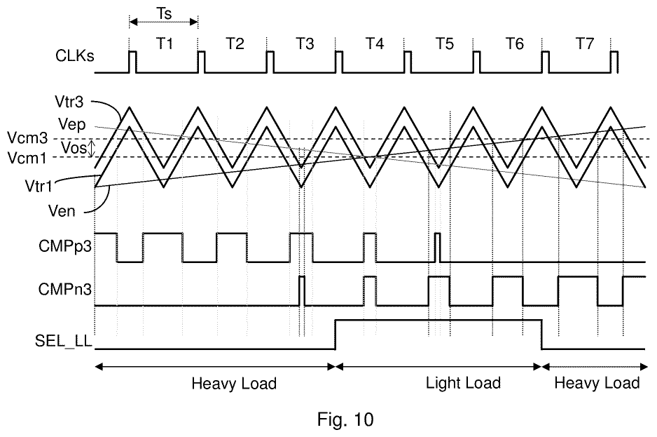

FIG. 10 illustrates a waveform diagram for generating the light-load selection signal SEL_LL in one embodiment of the present invention. Signals such as triangular wave signal Vtr1, offset triangular wave Vtr3, common-mode offset Vos, filtered signals Vep and Ven, common-mode levels Vcm1 and Vcm3, clock signal CLK, pulse-width modulation signals CMPp3 and CMPn3, and light-load selection signal SEL_LL are shown in FIG. 10. Referring to both FIG. 10 and FIG. 11, in this embodiment, the light-load selection signal SEL_LL is generated by performing logical operations between filtered signals Vep and Ven using triangular wave signal Vtr1 and offset triangular wave Vtr3, determining whether the differential input signal Vid is within the light-load range. In one embodiment, the offset triangular wave Vtr3 is obtained by adding a nonzero common-mode offset Vos to triangular wave signal Vtr1, with both having the same amplitude Va1 and Va2. Pulse-width modulation signals CMPp3 and CMPn3 are generated by comparing the offset triangular wave Vtr3 with the filtered signals Vep and Ven respectively. The signal judgment circuit periodically determines, based on the operating cycle of offset triangular wave Vtr3, whether each of the pulse-width modulation signals CMPp3 and CMPn3 includes a pulse in the previous cycle, thereby determining whether the level of Vid is within the light-load range. In one embodiment, the common-mode offset Vos is related to the light-load range. In this embodiment, the common-mode level of Vtr1 is related to (e.g., equal to) the common-mode level of the filtered signals Vep and Ven.

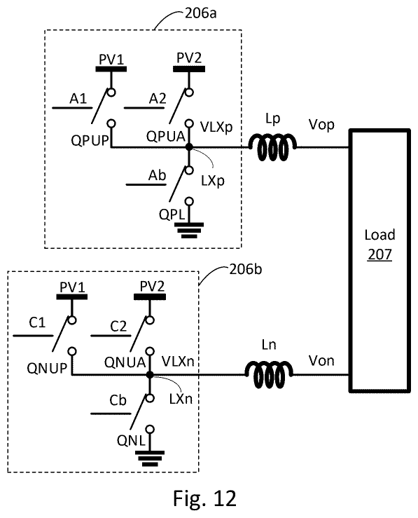

FIG. 12 illustrates a schematic diagram of an alternative embodiment of power stage circuits 206a and 206b. This embodiment is similar to the power stage circuits shown in FIG. 2B, with the difference being that the switching voltage VLXn is configured to switch the inductor Ln to generate the output signal Von, wherein the inductance of Ln is smaller than that of Lp. According to the present invention, optionally, switching voltage VLXn can directly serve as the output signal Von, or as in this embodiment, VLXn switches the inductor Ln to generate the output signal Von. Due to the aforementioned characteristics inherent in the design of the present invention, the inductance of Ln can be reduced, or Ln can even be eliminated, thereby reducing size and cost.

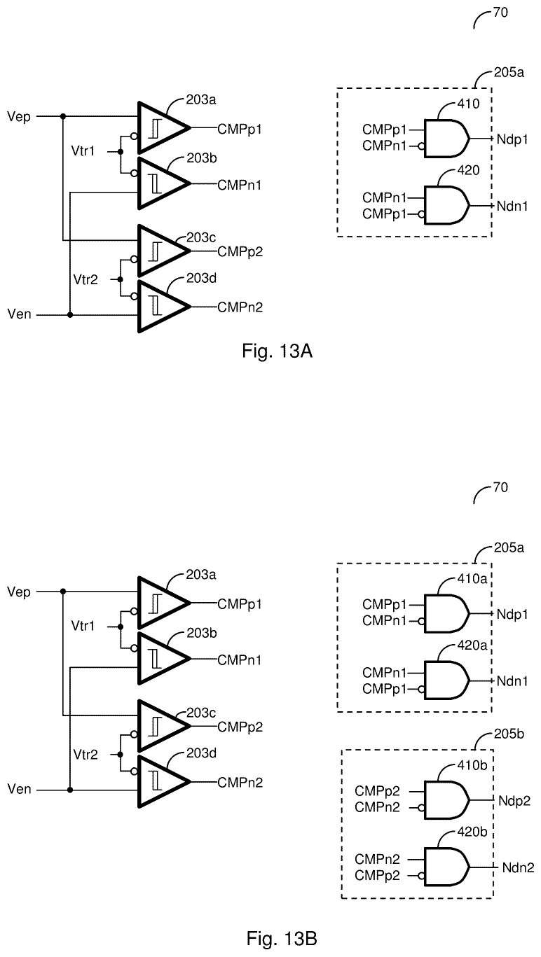

FIG. 13A illustrates a specific embodiment of the pulse-width modulation circuits and masking frequency-doubler circuits in the hybrid differential amplifier according to one embodiment of the present invention. Pulse-width modulation circuits 203a-203d in this embodiment are identical to those in FIG. 2A and will not be described in detail. As shown in FIG. 13A, the masking frequency-doubler circuit 205a includes AND gates 410 and 420. AND gate 410 is configured to apply a logical AND operation to pulse-width modulation signal CMPp1 and the inverted signal of the pulse-width modulation signal CMPn1 to generate the pulse-width masking frequency-doubled signal Ndp1. AND gate 420 is configured to apply a logical AND operation to the inverted signal of the pulse-width modulation signal CMPp1 and the pulse-width modulation signal CMPn1 to generate the pulse-width masking frequency-doubled signal Ndn1.

FIG. 13B illustrates another specific embodiment of the pulse-width modulation circuits and masking frequency-doubler circuits in the hybrid differential amplifier according to an alternative embodiment of the present invention. Pulse-width modulation circuits 203a-203d and masking frequency-doubler circuit 205a in this embodiment are similar to those in FIG. 13A and will not be described in detail. As shown in FIG. 13B, masking frequency-doubler circuit 205b includes AND gates 410b and 420b. AND gate 410b is configured to apply a logical AND operation to the pulse-width modulation signal CMPp2 and the inverted signal of the pulse-width modulation signal CMPn2 to generate the pulse-width masking frequency-doubled signal Ndp2. AND gate 420b is configured to apply a logical AND operation to the inverted signal of the pulse-width modulation signal CMPp2 and the pulse-width modulation signal CMPn2 to generate the pulse-width masking frequency-doubled signal Ndn2.

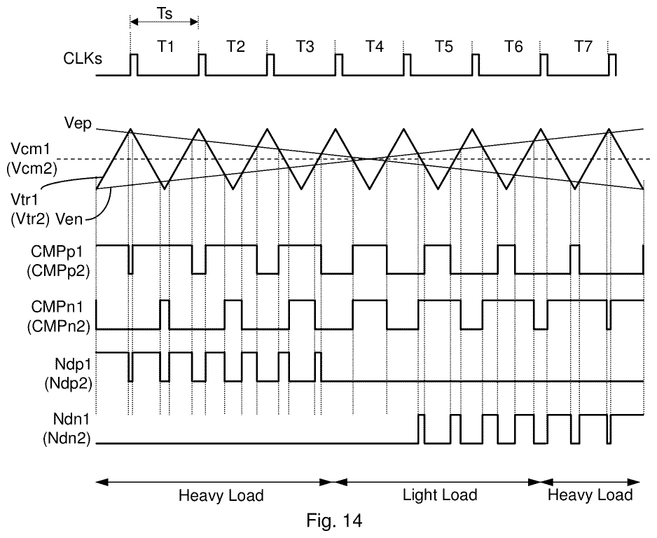

FIG. 14 illustrates the waveform diagram of signals corresponding to the embodiments shown in FIG. 13A and FIG. 13B. Signals such as triangular wave signals Vtr1 and Vtr2, filtered signals Vep and Ven, common-mode levels Vcm1 and Vcm2, clock signal CLK, pulse-width modulation signals CMPp1, CMPp2, CMPn1, and CMPn2, and pulse-width masking frequency-doubled signals Ndp1, Ndp2, Ndn1, and Ndn2 are depicted in FIG. 14. As shown, when the filtered signal Vep exceeds its common-mode level, the pulse-width masking frequency-doubled signal Ndp1 exhibits the frequency-doubled characteristics of pulse-width modulation signals CMPp1. When the filtered signal Vep is below its common-mode level, the pulse-width masking frequency-doubled signal Ndp1 is masked to 0. The pulse-width masking frequency-doubled signal Ndp1 exhibits a symmetric waveform. pulse-width masking frequency-doubled signals Ndp2 and Ndn2 show similar characteristics.

The present invention has been described in considerable detail with reference to certain preferred embodiments thereof. It should be understood that the description is for illustrative purpose, not for limiting the broadest scope of the present invention. An embodiment or a claim of the present invention does not need to achieve all the objectives or advantages of the present invention. The title and abstract are provided for assisting searches but not for limiting the scope of the present invention. Those skilled in this art can readily conceive variations and modifications within the spirit of the present invention. For example, to perform an action “according to” a certain signal as described in the context of the present invention is not limited to performing an action strictly according to the signal itself, but can be performing an action according to a converted form or a scaled-up or down form of the signal, i.e., the signal can be processed by a voltage-to-current conversion, a current-to-voltage conversion, and/or a ratio conversion, etc. before an action is performed. It is not limited for each of the embodiments described hereinbefore to be used alone; under the spirit of the present invention, two or more of the embodiments described hereinbefore can be used in combination. For example, two or more of the embodiments can be configured together, or, a part of one embodiment can be configured to replace a corresponding part of another embodiment. In view of the foregoing, the spirit of the present invention should cover all such and other modifications and variations, which should be interpreted to fall within the scope of the following claims and their equivalents.

What is claimed is:

1. A hybrid differential amplifier configured to generate a differential output signal based on a differential input signal to drive a load, wherein the differential input signal includes a first input signal and a second input signal, and the differential output signal includes a first output signal and a second output signal, the hybrid differential amplifier comprising:
a first pulse-width modulation (PWM) circuit, configured to generate a first PWM signal by comparing a first triangular wave signal with a first filtered signal, wherein the first filtered signal is related to the first input signal;
a second PWM circuit, configured to generate a second PWM signal by comparing the first triangular wave signal with a second filtered signal, wherein the second filtered signal is related to the second input signal;
a third PWM circuit, configured to generate a third PWM signal by comparing a second triangular wave signal with the first filtered signal;
a fourth PWM circuit, configured to generate a fourth PWM signal by comparing the second triangular wave signal with the second filtered signal;
a first masking frequency-doubler circuit, configured to generate a first pulse-width masking frequency-doubled signal and a second pulse-width masking frequency-doubled signal based on the first PWM signal and the second PWM signal, wherein:
when the first input signal is positive, the first pulse-width masking frequency-doubled signal corresponds to a frequency-doubled signal of the first PWM signal, and when the first input signal is negative, the first pulse-width masking frequency-doubled signal is 0;
when the second input signal is positive, the second pulse-width masking frequency-doubled signal corresponds to a frequency-doubled signal of the second PWM signal, and when the second input signal is negative, the second pulse-width masking frequency-doubled signal is 0;
a signal judgment circuit, configured to generate a path selection signal based on the level range of the differential input signal;
a signal selection circuit, configured to generate a first switching control signal and a second switching control signal based on the first pulse-width masking frequency-doubled signal, the second pulse-width masking frequency-doubled signal, the third PWM signal, and the fourth PWM signal, in response to the path selection signal;
a first power stage circuit, including a first plurality of transistors coupled to a first switching node, configured to generate a first switching voltage at the first switching node based on the first switching control signal, thereby switching a first inductor coupled to the first switching node to generate the first output signal;
a second power stage circuit, including a second plurality of transistors, configured to generate a second switching voltage at a second switching node based on the second switching control signal, thereby generating the second output signal;
wherein when the path selection signal indicates that the differential input signal is outside a light-load range:
the first switching control signal is selected as being related to the first pulse-width masking frequency-doubled signal with a first PWM characteristic to control the first switching voltage at the first switching node to toggle between a first supply voltage and a ground potential; and
the second switching control signal is selected as being approximating a fundamental frequency to control the second switching voltage at the second switching node to toggle between the first supply voltage and the ground potential, wherein the differential input signal has the fundamental frequency;
wherein when the path selection signal indicates that the differential input signal is within the light-load range:
the first switching control signal is selected as being related to the third PWM signal to control the first switching voltage to toggle between a second supply voltage and the ground potential, thereby switching the first inductor to generate the first output signal;
the second switching control signal is selected as being related to the fourth PWM signal to control the second switching voltage to toggle between the second supply voltage and the ground potential;
wherein the second supply voltage is lower than the first supply voltage.

2. The hybrid differential amplifier of claim 1, wherein the first triangular wave signal and the second triangular wave signal have a common-mode offset and respective first and second amplitudes, wherein the first amplitude is either equal to the second amplitude with a nonzero common-mode offset, or different from the second amplitude.

3. The hybrid differential amplifier of claim 1, wherein the second switching voltage either switches a second inductor with an inductance smaller than that of the first inductor to generate the second output signal, or corresponds to the second output signal.

4. The hybrid differential amplifier of claim 2, wherein the differential input signal has an input common-mode level, and the path selection signal includes a light-load selection signal and a level selection signal, wherein the signal judgment circuit generates the light-load selection signal based on whether the differential input signal is within a light-load range and generates the level selection signal based on the first pulse-width masking frequency-doubled signal and the second pulse-width masking frequency-doubled signal, the level selection signal represents a comparison between the differential input signal and the input common-mode level.

5. The hybrid differential amplifier of claim 4, wherein the signal judgment circuit includes a flip-flop configured to reset based on an inverted signal of the second pulse-width masking frequency-doubled signal and, in a non-reset state, configured to enable the level selection signal based on a trigger of the first pulse-width masking frequency-doubled signal.

6. The hybrid differential amplifier of claim 4, wherein the signal judgment circuit is further configured to compare an offset triangular wave with the differential input signal to generate a fifth PWM signal and a sixth PWM signal, wherein the offset triangular wave is obtained by superimposing the first triangular wave signal with a nonzero common-mode offset related to the light-load range; and configured to periodically determine, based on an operating cycle of the offset triangular wave, whether each of the fifth PWM signal and the sixth PWM signal includes a pulse respectively within the previous operating cycle, thereby determining whether the level of the differential input signal is within the light-load range.

7. The hybrid differential amplifier of claim 4, wherein when the path selection signal indicates that the differential input signal is outside the light-load range and greater than the input common-mode level:
the signal selection circuit controls the first switching control signal to toggle based on the first pulse-width masking frequency-doubled signal; and
the signal selection circuit controls the second switching control signal to toggle based on the second pulse-width masking frequency-doubled signal;
wherein when the path selection signal indicates that the differential input signal is outside the light-load range and less than the input common-mode level:
the signal selection circuit controls the first switching control signal to toggle based on an inverted signal of the second pulse-width masking frequency-doubled signal; and
the signal selection circuit controls the second switching control signal to toggle based on an inverted signal of the first pulse-width masking frequency-doubled signal.

8. The hybrid differential amplifier of claim 4, wherein when the path selection signal indicates that the differential input signal is within the light-load range:
the signal selection circuit controls the first switching control signal to toggle based on the third PWM signal; and
the signal selection circuit controls the second switching control signal to toggle based on the fourth PWM signal.

9. The hybrid differential amplifier of claim 1, further comprising:
a second masking frequency-doubler circuit configured to generate a third pulse-width masking frequency-doubled signal and a fourth pulse-width masking frequency-doubled signal based on the third PWM signal and the fourth PWM signal, wherein:
when the first input signal is positive, the third pulse-width masking frequency-doubled signal corresponds to a frequency-doubled signal of the third PWM signal, and when the first input signal is negative, the third pulse-width masking frequency-doubled signal is 0;
when the second input signal is positive, the fourth pulse-width masking frequency-doubled signal corresponds to a frequency-doubled signal of the fourth PWM signal, and when the second input signal is negative, the fourth pulse-width masking frequency-doubled signal is 0;
wherein when the path selection signal indicates that the differential input signal is within the light-load range and greater than the input common-mode level:
the signal selection circuit controls the first switching control signal to toggle based on the third pulse-width masking frequency-doubled signal; and
the signal selection circuit controls the second switching control signal to toggle based on the fourth pulse-width masking frequency-doubled signal.
wherein when the path selection signal indicates that the differential input signal is within the light-load range and less than the input common-mode level:
the signal selection circuit controls the first switching control signal to toggle based on an inverted signal of the fourth pulse-width masking frequency-doubled signal; and
the signal selection circuit controls the second switching control signal to toggle based on an inverted signal of the third pulse-width masking frequency-doubled signal.

10. The hybrid differential amplifier of claim 1, wherein the first masking frequency-doubler circuit applies an AND logic operation to the first PWM signal and an inverted signal of the second PWM signal to generate the first pulse-width masking frequency-doubled signal, and applies an AND logic operation to an inverted signal of the first PWM signal and the second PWM signal to generate the second pulse-width masking frequency-doubled signal.

11. The hybrid differential amplifier of claim 9, wherein:
the first masking frequency-doubler circuit applies an AND logic operation to the first PWM signal and an inverted signal of the second PWM signal to generate the first pulse-width masking frequency-doubled signal, and applies an AND logic operation to an inverted signal of the first PWM signal and the second PWM signal to generate the second pulse-width masking frequency-doubled signal;
the second masking frequency-doubler circuit applies an AND logic operation to the third PWM signal and an inverted signal of the fourth PWM signal to generate the third pulse-width masking frequency-doubled signal, and applies an AND logic operation to an inverted signal of the third PWM signal and the fourth PWM signal to generate the fourth pulse-width masking frequency-doubled signal.

12. The hybrid differential amplifier of claim 9, wherein:
the first power stage circuit includes a first primary high-side transistor, a first auxiliary high-side transistor, and a first low-side transistor, wherein:
the first primary high-side transistor is coupled between the first supply voltage and the first switching node;
the first auxiliary high-side transistor is coupled between the second supply voltage and the first switching node;
the first low-side transistor is coupled between the first switching node and the ground potential;
the first power stage circuit is configured to generate the first switching voltage based on the first switching control signal to switch the first inductor, thereby converting the first supply voltage and the second supply voltage to generate the first output signal;
the second power stage circuit includes a second primary high-side transistor, a second auxiliary high-side transistor, and a second low-side transistor, wherein:
the second primary high-side transistor is coupled between the first supply voltage and the second switching node;
the second auxiliary high-side transistor is coupled between the second supply voltage and the second switching node;
the second low-side transistor is coupled between the second switching node and the ground potential;
the second power stage circuit is configured to switch based on the second switching control signal to convert the first supply voltage and the second supply voltage to generate the second output signal.

13. The hybrid differential amplifier of claim 12, further comprising:
an error amplifier configured to generate an error amplified signal based on a difference between a feedback signal related to the second output signal and the second filtered signal;
wherein in an ultra-light-load range, the signal selection circuit selects the error amplified signal to linearly control the second primary high-side transistor, adjusting the second output signal to be linearly related to the second filtered signal;
wherein the ultra-light-load range is a subset of the light-load range and represents conditions with load levels smaller than those in the light-load range.

14. A hybrid differential amplification method for controlling a hybrid differential amplifier to generate a differential output signal based on a differential input signal to drive a load, wherein the differential input signal includes a first input signal and a second input signal, and the differential output signal includes a first output signal and a second output signal, the hybrid differential amplification method comprising:
generating a first pulse-width modulation (PWM) signal by comparing a first triangular wave signal with a first filtered signal, wherein the first filtered signal is related to the first input signal;
generating a second PWM signal by comparing the first triangular wave signal with a second filtered signal, wherein the second filtered signal is related to the second input signal;
generating a third PWM signal by comparing a second triangular wave signal with the first filtered signal;
generating a fourth PWM signal by comparing the second triangular wave signal with the second filtered signal;
generating a first pulse-width masking frequency-doubled signal and a second pulse-width masking frequency-doubled signal based on the first PWM signal and the second PWM signal, wherein:
when the first input signal is positive, the first pulse-width masking frequency-doubled signal corresponds to a frequency-doubled signal of the first PWM signal, and when the first input signal is negative, the first pulse-width masking frequency-doubled signal is 0;
when the second input signal is positive, the second pulse-width masking frequency-doubled signal corresponds to a frequency-doubled signal of the second PWM signal, and when the second input signal is negative, the second pulse-width masking frequency-doubled signal is 0;
generating a path selection signal based on the level range of the differential input signal;
generating a first switching control signal and a second switching control signal based on the first pulse-width masking frequency-doubled signal, the second pulse-width masking frequency-doubled signal, the third PWM signal, and the fourth PWM signal, in response to the path selection signal;
generating a first switching voltage at a first switching node based on the first switching control signal, thereby switching a first inductor coupled to the first switching node to generate the first output signal;
generating a second switching voltage at a second switching node based on the second switching control signal, thereby generating the second output signal;
wherein when the path selection signal indicates that the differential input signal is outside a light-load range, the first switching control signal is selected as being related to the first pulse-width masking frequency-doubled signal with a first PWM characteristic to control the first switching voltage at the first switching node to toggle between a first supply voltage and a ground potential, and the second switching control signal is selected as being related to a signal approximating a fundamental frequency to control the second switching voltage at the second switching node to toggle between the first supply voltage and the ground potential, wherein the differential input signal has the fundamental frequency;
wherein when the path selection signal indicates that the differential input signal is within the light-load range, the first switching control signal is selected as being related to the third PWM signal to control the first switching voltage to toggle between a second supply voltage and a ground potential, thereby switching the first inductor to generate the first output signal, and the second switching control signal is selected as being related to the fourth PWM signal to control the second switching voltage to toggle between the second supply voltage and a ground potential;
wherein the second supply voltage is lower than the first supply voltage.

15. The hybrid differential amplification method of claim 14, wherein the first triangular wave signal and the second triangular wave signal have a common-mode offset and respective first and second amplitudes; wherein the first amplitude is either equal to the second amplitude with a nonzero common-mode offset, or different from the second amplitude.

16. The hybrid differential amplification method of claim 14, wherein the second switching voltage either switches a second inductor with an inductance smaller than that of the first inductor to generate the second output signal, or corresponds to the second output signal.

17. The hybrid differential amplification method of claim 15, wherein the differential input signal has an input common-mode level, and the path selection signal includes a light-load selection signal and a level selection signal; wherein the step of generating the path selection signal includes generating the light-load selection signal based on whether the differential input signal is within a light-load range and generating the level selection signal based on the first pulse-width masking frequency-doubled signal and the second pulse-width masking frequency-doubled signal; wherein the level selection signal represents a comparison between the differential input signal and the input common-mode level.

18. The hybrid differential amplification method of claim 17, wherein the step of generating the level selection signal includes: resetting the level selection signal based on an inverted signal of the second pulse-width masking frequency-doubled signal; and in a non-reset state, enabling the level selection signal based on a trigger of the first pulse-width masking frequency-doubled signal.

19. The hybrid differential amplification method of claim 17, wherein the step of generating the light-load selection signal includes:
comparing an offset triangular wave with the differential input signal to generate a fifth PWM signal and a sixth PWM signal, wherein the offset triangular wave is obtained by superimposing the first triangular wave signal with a nonzero common-mode offset related to the light-load range; and
periodically determining, based on an operating cycle of the offset triangular wave, whether each of the fifth PWM signal and the sixth PWM signal includes a pulse within the previous operating cycle, thereby determining whether the level of the differential input signal is within the light-load range.

20. The hybrid differential amplification method of claim 17, wherein the step of generating the level selection signal includes:
when the path selection signal indicates that the differential input signal is outside the light-load range and greater than the input common-mode level, controlling the first switching control signal to toggle based on the first pulse-width masking frequency-doubled signal and controlling the second switching control signal to toggle based on the second pulse-width masking frequency-doubled signal; and
when the path selection signal indicates that the differential input signal is outside the light-load range and less than the input common-mode level, controlling the first switching control signal to toggle based on an inverted signal of the second pulse-width masking frequency-doubled signal and controlling the second switching control signal to toggle based on an inverted signal of the first pulse-width masking frequency-doubled signal.

21. The hybrid differential amplification method of claim 17, wherein the step of generating the first switching control signal and the second switching control signal includes:
when the path selection signal indicates that the differential input signal is within the light-load range, controlling the first switching control signal to toggle based on the third PWM signal and controlling the second switching control signal to toggle based on the fourth PWM signal.

22. The hybrid differential amplification method of claim 14, further including:
generating a third pulse-width masking frequency-doubled signal and a fourth pulse-width masking frequency-doubled signal based on the third PWM signal and the fourth PWM signal, wherein:
when the first input signal is positive, the third pulse-width masking frequency-doubled signal corresponds to a frequency-doubled signal of the third PWM signal, and when the first input signal is negative, the third pulse-width masking frequency-doubled signal is 0;
when the second input signal is positive, the fourth pulse-width masking frequency-doubled signal corresponds to a frequency-doubled signal of the fourth PWM signal, and when the second input signal is negative, the fourth pulse-width masking frequency-doubled signal is 0;
wherein when the path selection signal indicates that the differential input signal is within the light-load range and greater than the input common-mode level, the first switching control signal is controlled to toggle based on the third pulse-width masking frequency-doubled signal and the second switching control signal is controlled to toggle based on the fourth pulse-width masking frequency-doubled signal;
wherein when the path selection signal indicates that the differential input signal is within the light-load range and less than the input common-mode level, the first switching control signal is controlled to toggle based on an inverted signal of the fourth pulse-width masking frequency-doubled signal and the second switching control signal is controlled to toggle based on an inverted signal of the third pulse-width masking frequency-doubled signal.

23. The hybrid differential amplification method of claim 14, wherein the step of generating the first pulse-width masking frequency-doubled signal and the second pulse-width masking frequency-doubled signal includes:
applying an AND logic operation to the first PWM signal and an inverted signal of the second PWM signal to generate the first pulse-width masking frequency-doubled signal; and
applying an AND logic operation to an inverted signal of the first PWM signal and the second PWM signal to generate the second pulse-width masking frequency-doubled signal.

24. The hybrid differential amplification method of claim 22, wherein the step of generating the first pulse-width masking frequency-doubled signal and the second pulse-width masking frequency-doubled signal includes:
applying an AND logic operation to the first PWM signal and an inverted signal of the second PWM signal to generate the first pulse-width masking frequency-doubled signal; and
applying an AND logic operation to an inverted signal of the first PWM signal and the second PWM signal to generate the second pulse-width masking frequency-doubled signal;
wherein the step of generating the third pulse-width masking frequency-doubled signal and the fourth pulse-width masking frequency-doubled signal includes:
applying an AND logic operation to the third PWM signal and an inverted signal of the fourth PWM signal to generate the third pulse-width masking frequency-doubled signal; and
applying an AND logic operation to an inverted signal of the third PWM signal and the fourth PWM signal to generate the fourth pulse-width masking frequency-doubled signal.

25. The hybrid differential amplification method of claim 22, further comprising:
generating an error amplified signal based on a difference between a feedback signal related to the second output signal and the second filtered signal;
wherein in an ultra-light-load range, the error amplified signal is selected to linearly control the second primary high-side transistor, adjusting the second output signal to be linearly related to the second filtered signal;
wherein the ultra-light-load range is a subset of the light-load range and represents conditions with load levels smaller than those in the light-load range.
